(19) United States
(12) Patent Application Publication
(10) Pub. No.: US 2025/0020730 A1
(43) Pub. Date: Jan. 16, 2025

(54) STORAGE BATTERY DEGRADATION ESTIMATION DEVICE AND STORAGE BATTERY DEGRADATION ESTIMATION METHOD

(71) Applicant: Nuvoton Technology Corporation Japan, Kyoto (JP)

(72) Inventors: Kazuyuki KOUNO, Osaka (JP); Toshio MATSUKI, Kyoto (JP); Masayoshi NAKAYAMA, Kyoto (JP); Takashi ONO, Osaka (JP); Hitoshi SUWA, Osaka (JP); Reiji MOCHIDA, Osaka (JP)

(21) Appl. No.: 18/897,258

(22) Filed: Sep. 26, 2024

Related U.S. Application Data
(63) Continuation of application No. PCT/JP2023/009114, filed on Mar. 9, 2023.

(30) Foreign Application Priority Data
Mar. 30, 2022 (JP) 2022-057346

(51) Int. Cl. G01R 31/392; G01R 31/36; G01R 31/367; G01R 31/388

(52) U.S. Cl. CPC G01R 31/392; G01R 31/3648; G01R 31/367; G01R 31/388

(57) ABSTRACT

A degradation estimation device includes: a first calculator that calculates a voltage change amount from a first voltage value and a second voltage value measured when the storage battery is charged and discharged; a second calculator that calculates an electric charge change amount from a first current value and a second current value when the storage battery is charged and discharged; a data storage that stores measured data that includes the voltage change amount and the electric charge change amount; a model storage that stores an estimation model that uses one or more electric charge change amounts as inputs and outputs the degradation state of the storage battery; and an estimator that estimates the degradation state of the storage battery by using the estimation model and using, as inputs, the one or more voltage change amounts and the one or more electric charge change amounts.

### CROSS REFERENCE TO RELATED APPLICATIONS

This is a continuation application of PCT International Application No. PCT/JP2023/009114 filed on Mar. 9, 2023, designating the United States of America, which is based on and claims priority of Japanese Patent Application No. 2022-057346 filed on Mar. 30, 2022. The entire disclosures of the above-identified applications, including the specifications, drawings and claims are incorporated herein by reference in their entirety.

### FIELD

The present disclosure relates to a storage battery degradation estimation device and a storage battery degradation estimation method.

### BACKGROUND

In recent years, devices that operate on battery power, such as storage batteries, have been used in a wide range of fields. In order to use these devices safely, it is necessary to prevent a situation in which the storage batteries run out of power or have a malfunction, and it is necessary to accurately assess the state of degradation of the storage batteries.

As one of the indexes indicating the degradation state of a storage battery, the capacity retention rate (state of health (SOH)) is used. A storage battery degrades with continued use, and the full charge capacity of the storage battery after degradation has a property to become lower than the initial full charge capacity of the storage battery. The capacity retention rate (SOH) is defined by the ratio of the full charge capacity after degradation to the initial full charge capacity, and the smaller the value of the capacity retention rate (SOH), the more the storage battery is degraded.

One method for calculating the capacity retention rate (SOH) of a storage battery is coulomb counting which calculates the capacity retention rate (SOH) by integrating the charge current until a completely discharged storage battery is fully charged to calculate the full charge capacity and dividing the calculated full charge capacity by the initial full charge capacity.

Another method for calculating the capacity retention rate (SOH) of a storage battery is SOC-OCV curve method that measures the capacity retention rate (SOH) by measuring the open circuit voltage (OCV) at the time of full charge, calculating the full charge capacity from the state of charge (SOC)-OCV curve, and dividing the full charge capacity by the initial full charge capacity.

As another method for calculating the capacity retention rate (SOH) of a storage battery, a machine learning method to which artificial intelligence (AI) technique has been applied has been developed in recent years. In the machine learning method, the capacity retention rate (SOH) of a storage battery is calculated by using an estimation model trained by machine learning with the various states of the storage battery as inputs and the capacity retention rate (SOH) of the storage battery as an output. Patent Literature (PTL) 1 and PTL 2 disclose storage battery degradation estimation devices that use the machine learning method.

### CITATION LIST

### Patent Literature

[PTL 1] Japanese Unexamined Patent Application Publication No. 2021-185354
[PTL 2] International Application Publication No. WO2021/241115

### SUMMARY

### Technical Problem

However, for each of the coulomb counting, the SOC-OCV curve method, and the machine learning method disclosed in PTL 1 and PTL 2, for calculating the capacity retention rate (SOH) of a storage battery, the following problems exit.

The coulomb counting for calculating the capacity retention rate (SOH) of a storage battery requires the storage battery to be fully charged from a completely discharged state. It is inconvenient to perform such a process on a device in which the storage battery has been mounted. In addition, it is difficult to calculate the capacity retention rate (SOH) by using this method when the device with the storage battery is always in operation.

In the SOC-OCV method for calculating the capacity retention rate (SOH) of a storage battery, the property of the SOC-OCV curve varies in accordance with the temperature and the degradation state of the storage battery. Therefore, calculation errors occur due to the property variations. In order to address the property variations in the SOC-OCV curve, it is necessary to switch between a plurality of SOC-OCV curves for application. However, even in this case, calculation errors occur due to erroneous switching. Furthermore, in addition to being capable of calculating the capacity retention rate (SOH) only when a full charge is completed, the OCV voltage must be measured, which makes it difficult to calculate the capacity retention rate (SOH) when the device with the storage battery is always in operation.

Moreover, the methods for calculating the capacity retention rate (SOH) of a storage battery by the machine learning methods disclosed in PTL 1 and PTL 2 require measured data of the storage battery when full charges of the storage battery are completed a plurality of times or until full charges are completed a plurality of times. Therefore, it is difficult to immediately calculate the capacity retention rate (SOH) while the storage battery is in use.

The present disclosure has been conceived in view of the above problems. The present disclosure provides a storage battery degradation estimation device and a storage battery degradation estimation method that are capable of estimating the degradation state of a storage battery even when the storage battery is in use, and estimating the degradation state with higher accuracy.

### Solution to Problem

A storage battery degradation estimation device according to the present disclosure includes: a first calculator that calculates a voltage change amount that is an amount of change in a voltage of the storage battery obtained from a first voltage value and a second voltage value that are measured when the storage battery is charged and discharged, the second voltage value being measured after the first voltage value; a second calculator that calculates an electric charge change amount that is an amount of change in an electric charge of the storage battery obtained from a first current value and a second current value that are measured when the storage battery is charged and discharged, the second current value being measured after the first current value; a measured data storage that stores a plurality of items of measured data that include the voltage change amount and the electric charge change amount; an estimation model storage that stores an estimation model trained by machine learning, the estimation model using one or more voltage change amounts and one or more electric charge change amounts as inputs and outputting the degradation state of the storage battery, the one or more voltage change amounts each being the voltage change amount, the one or more electric charge change amounts each being the electric charge change amount; and an estimator that estimates the degradation state of the storage battery by using the estimation model stored in the estimation model storage, the estimator using, as inputs, the one or more voltage change amounts and the one or more electric charge change amounts stored in the measured data storage.

A storage battery degradation estimation device according to the present disclosure includes: a first calculator that calculates a voltage change amount that is an amount of change in a voltage of the storage battery obtained from a first voltage value and a second voltage value that are measured when the storage battery is charged and discharged, the second voltage value being measured after the first voltage value; a second calculator that calculates an electric charge change amount that is an amount of change in an electric charge of the storage battery obtained from a first current value and a second current value that are measured when the storage battery is charged and discharged, the second current value being measured after the first current value; a measured data storage that stores a plurality of items of measured data that include the voltage change amount and the electric charge change amount; an estimation model storage that stores an estimation model trained by machine learning, the estimation model using one or more voltage change amounts and one or more electric charge change amounts as inputs and outputting the degradation state of the storage battery, the one or more voltage change amounts each being the voltage change amount, the one or more electric charge change amounts each being the electric charge change amount; an estimator that estimates the degradation state of the storage battery by using the estimation model stored in the estimation model storage, the estimator using, as inputs, the one or more voltage change amounts and the one or more electric charge change amounts stored in the measured data storage; and a low-pass filtering unit that uses, as an input, the degradation state of the storage battery output from the estimator, smoothes the degradation state of the storage battery by using a low-pass filter to obtain a smoothed degradation state of the storage battery, and outputs the smoothed degradation state.

A storage battery degradation estimation device according to the present disclosure includes: a first low-pass filtering unit that uses, as an input, a voltage measured when the storage battery is charged and discharged, smoothes the voltage by using a low-pass filter to obtain a smoothed voltage, and outputs the smoothed voltage; a first calculator that calculates a smoothed voltage change amount that is an amount of change in the smoothed voltage of the storage battery obtained from a first smoothed voltage value and a second smoothed voltage value that are output from the first low-pass filtering unit, the second smoothed voltage value being output after the first smoothed voltage value; a second low-pass filtering unit that uses, as an input, a current measured when the storage battery is charged and discharged, smoothes the current by using a low-pass filter to obtain a smoothed current, and outputs the smoothed current; a second calculator that calculates a smoothed electric charge change amount that is an amount of change in a smoothed electric charge of the storage battery obtained from a first smoothed current value and a second smoothed current value that are output from the second low-pass filtering unit, the second smoothed current value being output after the first smoothed current value; a measured data storage that stores a plurality of items of measured data that include the smoothed voltage change amount and the smoothed electric charge change amount; an estimation model storage that stores an estimation model trained by machine learning, the estimation model using one or more smoothed voltage change amounts and one or more smoothed electric charge change amounts as inputs and outputting the degradation state of the storage battery, the one or more smoothed voltage change amounts each being the smoothed voltage change amount, the one or more electric charge change amounts each being the smoothed electric charge change amount; and an estimator that estimates the degradation state of the storage battery by using the estimation model stored in the estimation model storage, the estimator using, as inputs, the one or more smoothed voltage change amounts and the one or more smoothed electric charge change amounts stored in the measured data storage.

A storage battery degradation estimation device according to the present disclosure includes: a first low-pass filtering unit that uses, as an input, a voltage measured when the storage battery is charged and discharged, smoothes the voltage by using a low-pass filter to obtain a smoothed voltage, and outputs the smoothed voltage; a first calculator that calculates a smoothed voltage change amount that is an amount of change in the smoothed voltage of the storage battery obtained from a first smoothed voltage value and a second smoothed voltage value that are output from the first low-pass filtering unit, the second smoothed voltage value being output after the first smoothed voltage value; a second low-pass filtering unit that uses, as an input, a current measured when the storage battery is charged and discharged, smoothes the current by using a low-pass filter to obtain a smoothed current, and outputs the smoothed current; a second calculator that calculates a smoothed electric charge change amount that is an amount of change in a smoothed electric charge of the storage battery obtained from a first smoothed current value and a second smoothed current value that are output from the second low-pass filtering unit, the second smoothed current value being output after the first smoothed current value; a measured data storage that stores a plurality of items of measured data that include the smoothed voltage change amount and the smoothed electric charge change amount; an estimation model storage that stores an estimation model trained by machine learning, the estimation model using one or more smoothed voltage change amounts and one or more smoothed electric charge change amounts as inputs and outputting the degradation state of the storage battery, the one or more smoothed voltage change amounts each being the smoothed voltage change amount, the one or more electric charge change amounts each being the smoothed electric charge change amount; an estimator that estimates the degradation state of the storage battery by using the estimation model stored in the estimation model storage, the estimator using, as inputs, the one or more smoothed voltage change amounts and the one or more smoothed electric charge change amounts stored in the measured data storage; and a third low-pass filtering unit that uses, as an input, the degradation state of the storage battery output from the estimator, smoothes the degradation state of the storage battery by using a low-pass filter to obtain a smoothed degradation state of the storage battery, and outputs the smoothed degradation state.

Moreover, in the storage battery degradation estimation device according to the present disclosure, it may be that the degradation state of the storage battery is a capacity retention rate of the storage battery or a full charge capacity value of the storage battery.

Moreover, it may be that the storage battery degradation estimation device further includes: a reception communicator that receives a new estimation model from outside of the storage battery degradation estimation device; and an updater that updates the estimation model stored in the estimation model storage to the new estimation model received by the reception communicator.

Moreover, it may be that the storage battery degradation estimation device further includes: an estimated data storage that stores the degradation state of the storage battery estimated by the estimator; and a transmission communicator that transmits the plurality of items of measured data stored in the measured data storage and the degradation state of the storage battery stored in the estimated data storage to outside of the storage battery degradation estimation device.

A storage battery degradation estimation method according to the present disclosure includes: calculating a voltage change amount that is an amount of change in a voltage of the storage battery obtained from a first voltage value and a second voltage value that are measured when the storage battery is charged and discharged, the second voltage value being measured after the first voltage value; calculating an electric charge change amount that is an amount of change in an electric charge of the storage battery obtained from a first current value and a second current value that are measured when the storage battery is charged and discharged, the second current value being measured after the first current value; and estimating the degradation state of the storage battery by using an estimation model trained by machine learning, the estimating using one or more voltage change amounts and one or more electric charge change amounts as inputs, the estimation model using the one or more voltage change amounts and the one or more electric charge change amounts as inputs and outputting the degradation state of the storage battery, the one or more voltage change amounts each being the voltage change amount, the one or more electric charge change amounts each being the electric charge change amount.

A storage battery degradation estimation method according to the present disclosure includes: calculating a voltage change amount that is an amount of change in a voltage of the storage battery obtained from a first voltage value and a second voltage value that are measured when the storage battery is charged and discharged, the second voltage value being measured after the first voltage value; calculating an electric charge change amount that is an amount of change in an electric charge of the storage battery obtained from a first current value and a second current value that are measured when the storage battery is charged and discharged, the second current value being measured after the first current value; estimating the degradation state of the storage battery by using an estimation model trained by machine learning, the estimating using one or more voltage change amounts and one or more electric charge change amounts as inputs, the estimation model using the one or more voltage change amounts and the one or more electric charge change amounts as inputs and outputting the degradation state of the storage battery, the one or more voltage change amounts each being the voltage change amount, the one or more electric charge change amounts each being the electric charge change amount; and using the degradation state of the storage battery as an input, and smoothing the degradation state of the storage battery by using a low-pass filter to calculate a smoothed degradation state of the storage battery.

A storage battery degradation estimation method according to the present disclosure includes: using, as an input, a voltage measured when the storage battery is charged and discharged, and smoothing the voltage by using a low-pass filter to calculate a first smoothed voltage value and a second smoothed voltage value, the second smoothed current value being obtained after the first smoothed voltage value; calculating a smoothed voltage change amount that is an amount of change in a smoothed voltage of the storage battery obtained from the first smoothed voltage value and the second smoothed voltage value; using a current measured when the storage battery is charged and discharged, and smoothing the current by using a low-pass filter to calculate a first smoothed current value and a second smoothed current value, the second smoothed current value being obtained after the first smoothed current value; calculating a smoothed electric charge change amount that is an amount of change in a smoothed electric charge of the storage battery obtained from the first smoothed current value and the second smoothed current value; and estimating the degradation state of the storage battery by using an estimation model trained by machine learning, the estimating using one or more smoothed voltage change amounts and one or more smoothed electric charge change amounts as inputs, the estimation model using the one or more smoothed voltage change amounts and the one or more smoothed electric charge change amounts as inputs and outputting the degradation state of the storage battery, the one or more smoothed voltage change amounts each being the smoothed voltage change amount, the one or more smoothed electric charge change amounts each being the smoothed electric charge change amount.

A storage battery degradation estimation method according to the present disclosure includes: using, as an input, a voltage measured when the storage battery is charged and discharged, and smoothing the voltage by using a low-pass filter to calculate a first smoothed voltage value and a second smoothed voltage value, the second smoothed current value being obtained after the first smoothed voltage value; calculating a smoothed voltage change amount that is an amount of change in a smoothed voltage of the storage battery obtained from the first smoothed voltage value and the second smoothed voltage value; using a current measured when the storage battery is charged and discharged, and smoothing the current by using a low-pass filter to calculate a first smoothed current value and a second smoothed current value, the second smoothed current value being obtained after the first smoothed current value; calculating a smoothed electric charge change amount that is an amount of change in a smoothed electric charge of the storage battery obtained from the first smoothed current value and the second smoothed current value; estimating the degradation state of the storage battery by using an estimation model trained by machine learning, the estimating using one or more smoothed voltage change amounts and one or more smoothed electric charge change amounts as inputs, the estimation model using the one or more smoothed voltage change amounts and the one or more smoothed electric charge change amounts as inputs and outputting the degradation state of the storage battery, the one or more smoothed voltage change amounts each being the smoothed voltage change amount, the one or more smoothed electric charge change amounts each being the smoothed electric charge change amount; and using the degradation state of the storage battery as an input, and smoothing the degradation state of the storage battery by using a low-pass filter to calculate a smoothed degradation state of the storage battery.

Moreover, in the storage battery degradation estimation method according to the present disclosure, it may be that the degradation state of the storage battery is a capacity retention rate of the storage battery or a full charge capacity value of the storage battery.

### Advantageous Effects

With the storage battery degradation estimation device and the storage battery degradation estimation method according to the present disclosure, it is possible to estimate the degradation state of a storage battery even when the storage battery is in use, and to estimate the degradation state with higher accuracy.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 illustrates an overall configuration of a storage battery degradation estimation device according to Embodiment 1 of the present disclosure.

FIG. 2 is a diagram for explaining capacity retention rate (SOH) of a storage battery.

FIG. 3 is a diagram for explaining voltage measured when a storage battery according to Embodiment 1 of the present disclosure is charged and discharged, and calculation of the amount of change in voltage.

FIG. 4 is a diagram for explaining current measured when a storage battery according to Embodiment 1 of the present disclosure is charged and discharged, and the amount of change in electric charge.

FIG. 5 illustrates a configuration of a degradation state estimator according to Embodiment 1 of the present disclosure.

FIG. 6 illustrates another configuration of the degradation state estimator according to Embodiment 1 of the present disclosure.

FIG. 7 is a flowchart of a storage battery degradation estimation method according to Embodiment 1 of the present disclosure.

FIG. 8 illustrates the estimated results of degradation of the storage battery according to Embodiment 1 of the present disclosure.

FIG. 9 illustrates an overall configuration of a storage battery degradation estimation device according to Embodiment 2 of the present disclosure.

FIG. 10 is a flowchart of a storage battery degradation estimation method according to Embodiment 2 of the present disclosure.

FIG. 11 illustrates the estimated results of degradation of the storage battery according to Embodiment 2 of the present disclosure.

FIG. 12 illustrates an overall configuration of a storage battery degradation estimation device according to Embodiment 3 of the present disclosure.

FIG. 13 illustrates voltage measured when a storage battery according to Embodiment 3 of the present disclosure is charged and discharged, and smoothed voltage smoothed by using a low-pass filter.

FIG. 14 is a flowchart of a storage battery degradation estimation method according to Embodiment 3 of the present disclosure.

FIG. 15 illustrates an overall configuration of a storage battery degradation estimation device according to Embodiment 4 of the present disclosure.

FIG. 16 is a flowchart of a storage battery degradation estimation method according to Embodiment 4 of the present disclosure.

### DESCRIPTION OF EMBODIMENTS

The storage battery degradation estimation device and the storage battery degradation estimation method according to the present disclosure are capable of directly calculating the degradation state of the storage battery from the voltage change amount and the electric charge amount by using an estimation model trained by machine learning. The estimation model uses, as inputs, the voltage change amount and the electric charge change amount respectively obtained from the voltage value and the current value that can be measured while the storage battery is in use, and outputs the degradation state of the storage battery. Therefore, in the storage battery degradation estimation device and method according to the present disclosure, it is not necessary to perform calculation of the charge capacity required to charge a storage battery from a fully discharged state to a fully charged state, or measurement of the OCV voltage after the storage battery is fully charged that are necessary in the conventional techniques. In addition, the storage battery degradation estimation device and method are capable of estimating the degradation state of the storage battery even when the storage battery is in use. Moreover, it is not necessary to calculate the full charge capacity by using the SOC-OCV curve, which may lead to calculation errors due to property variations. Accordingly, it is possible to estimate the degradation state with higher accuracy. In addition, an estimation model that uses the voltage change amount and the electric charge change amount as inputs and outputs the degradation state of the storage battery is trained by machine learning by using a large amount of training data prepared. Accordingly, it is possible to estimate the degradation state in various usage conditions of the storage battery, making it possible to estimate the degradation state with higher accuracy.

Moreover, the degradation state of the storage battery calculated by using the estimation model is used as an input, and the degradation state of the storage battery is smoothed by using a low-pass filter and the smoothed degradation state is output. With this, even when the degradation state of the storage battery calculated by using the estimation model includes a large error relative to the actual degradation state of the storage battery at a given time, the data to be output is smoothed by filtering such that the data follows the previous output data and the smoothed data is output. Therefore, it is possible to estimate the degradation state with fewer errors.

Moreover, the degradation state of the storage battery is calculated by using an estimation model trained by machine learning. The estimation model uses, as inputs, the voltage and the current measured when the storage battery is charged and discharged, smoothes the voltage and the current of the storage battery by using a low-pass filter to output a smoothed voltage and a smoothed current, uses, as inputs, a smoothed voltage change amount and a smoothed current charge change amount respectively obtained from the smoothed voltage and the smoothed current, and outputs the degradation state of the storage battery. With this, even when the voltage and the current measured from the storage battery may be affected by sharp changes in charge and discharge current of the storage battery, measurement noise, and the like, causing discrete voltage changes and current changes that are not continuous for each measurement, the discrete voltage changes and current changes are smoothed by using a low-pass filter to follow the previously measured voltage and current. Accordingly, the voltage change amount and the electric charge change amount input to the estimation model that estimates the degradation state of the storage battery are continuous data. This makes it possible to eliminate the effects of noise and the like from the voltage change amount and the electric charge change amount. As a result, it is possible to estimate the degradation state of the storage battery with fewer errors.

Moreover, the storage battery degradation estimation device includes a reception communicator that receives an estimation model that estimates the degradation state of the storage battery from outside of the storage battery degradation estimation device and an updater that updates the estimation model stored in the degradation estimation device to a new estimation model received from the reception communicator. Accordingly, even after the degradation estimation device is installed in a product, it is possible to perform update to the estimation model that has been trained by adding new training data after the installation and is capable of estimating the degradation state of the storage battery with higher accuracy. Accordingly, it is possible to estimate the degradation state with higher accuracy.

Moreover, the storage battery degradation estimation device includes the measured data storage that stores a plurality of items of measured data measured and calculated by the degradation estimation device, the estimated data storage that stores the degradation state of the storage battery estimated by the degradation estimation device, and a transmission communicator that transmits, to the outside of the storage battery degradation estimation device, the plurality of items of measured data stored in the measured data storage and the degradation state of the storage battery stored in the estimated data storage. Accordingly, it is possible to collect the measured data of the storage battery when the degradation estimation device is used and the estimated data of the degradation state of the storage battery even after the degradation estimation device is installed in a product. Therefore, it is possible to add training data in various usage conditions of the storage battery. With this, it is possible to generate a new estimation model with higher accuracy and perform update to the new estimation model, making it possible to estimate the degradation state with higher accuracy.

Hereinafter, embodiments according to the present disclosure will be described with reference to the drawings.

Note that each of the embodiments described below shows a general or specific example. Numerical values, shapes, structural elements, arrangement positions and connection forms of the structural elements, steps, order of steps, and the like shown in the following embodiments are examples, and are not intended to limit the present disclosure. For example, a numerical value is not an expression that represents only a strict meaning of the value, but is an expression that includes a substantially same range, e.g., a range that includes a difference of approximately a few percent. Among the structural elements in the following embodiments, structural elements that are not described in the independent claims are described as arbitrary structural elements.

Note that the drawings are represented schematically and are not necessarily precise illustrations. As such, the scaling, etc., depicted in the drawings is not necessarily accurate. Throughout the figures, substantially identical elements are denoted by the same reference numerals, and redundant descriptions thereof are omitted or simplified.

The numerical values and numerical ranges in the description are not strict expressions, but they represent substantially equivalent ranges, and, for example, they may include a difference of approximately a few percent (for example, approximately 10%).

### Embodiment 1

### [Overall Configuration of Storage Battery Degradation Estimation Device]

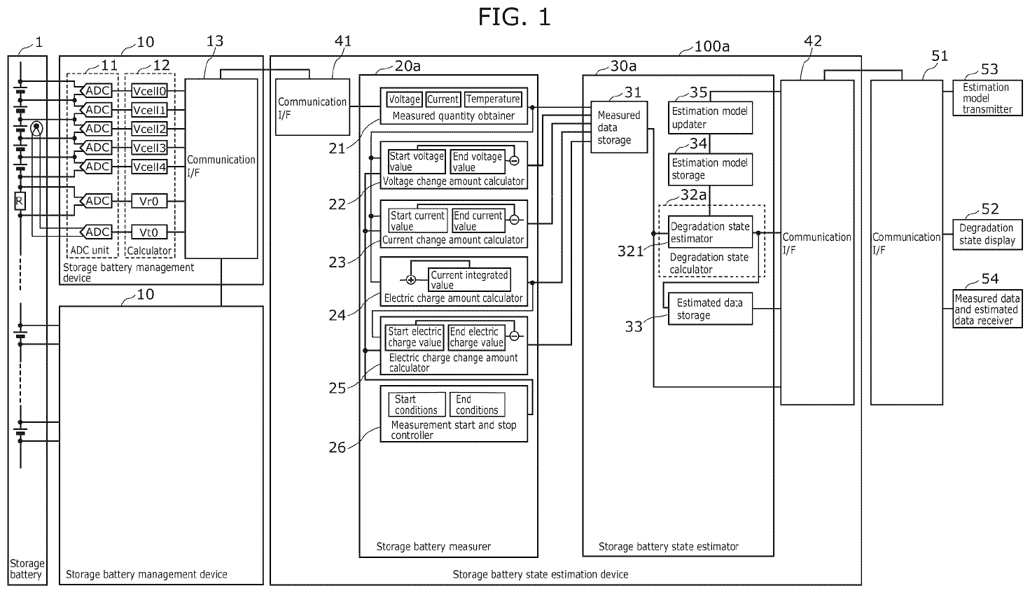

FIG. 1 illustrates an overall configuration of a storage battery degradation estimation device according to Embodiment 1 of the present disclosure.

Storage battery 1 includes a plurality of battery modules that are connected in series and in parallel.

Storage battery management device 10 is connected to storage battery 1 to measure the voltage, current, and temperature of storage battery 1. Storage battery management device 10 includes: analog to digital converter (ADC) unit 11 that converts analog signal values corresponding to the voltage, current, and temperature of storage battery 1 into digital signal values; calculator 12 that calculates the digital signal values that are the output of ADC unit 11 as the voltage value, current value, and temperature; and communication interface (I/F) 13 that transmits the voltage value, current value, and temperature calculated by calculator 12 to the outside of the storage battery degradation estimation device.

Storage battery state estimation device 100a includes: communication I/F 41 that receives the voltage value, current value, and temperature of storage battery 1 from storage battery management device 10; storage battery measurer 20a that processes the data received from communication I/F 41 to calculate various measured values of storage battery 1; storage battery state estimator 30a that receives the various measured values calculated by storage battery measurer 20a to estimate the degradation state of storage battery 1; and communication I/F 42 that transmits and receives, to and from the outside of the storage battery degradation estimation device, the degradation state of storage battery 1 calculated by storage battery state estimator 30a, an estimation model that estimates the degradation state of storage battery 1, and measured data and estimated data of storage battery 1. Storage battery state estimation device 100a is an example of a degradation estimation device.

Storage battery measurer 20a includes: measured quantity obtainer 21 that obtains the voltage value, current value, and temperature from communication I/F 41; voltage change amount calculator 22 that calculates the amount of change in voltage (voltage change amount) from a start voltage value that is a first voltage value and an end voltage value that is a second voltage value, by using the data stored in measured quantity obtainer 21; current change amount calculator 23 that calculates the amount of change in current (current change amount) from the start current value that is a first current value and an end current value that is a second current value; electric charge amount calculator 24 that calculates the amount of electric charge of storage battery 1 by integrating the current values; electric charge change amount calculator 25 that calculates the amount of change in electric charge (electric charge change amount) from a start electric charge amount and an end electric charge amount of storage battery 1, by using the amount of electric charge calculated by electric charge amount calculator 24; and measurement start and stop controller 26 that controls the start and end conditions necessary to calculate the voltage change amount, the current change amount, and the electric charge change amount described above. In other words, storage battery measurer 20a calculates various measurement parameters, such as the voltage change amount, the current change amount, and the electric charge change amount of storage battery 1 by using the voltage value and current value that are the measured data of storage battery 1. These measured data are transmitted to storage battery state estimator 30a described below.

Storage battery state estimator 30a includes: measured data storage 31 that stores the measured data obtained and calculated by storage battery measurer 20a; degradation state calculator 32a that estimates the degradation state of storage battery 1 by using the measured data stored in measured data storage 31 as input; degradation state estimator 321 that forms degradation state calculator 32a; estimated data storage 33 that stores the degradation state of storage battery 1 estimated by degradation state calculator 32a; estimation model storage 34 that stores an estimation model which has been trained by machine learning and which is used by degradation state estimator 321 for estimating the degradation state of storage battery 1; and estimation model updater 35 that receives a new estimation model from the outside of the storage battery degradation estimation device and updates the estimation model stored in estimation model storage 34.

Communication I/F 51 transmits and receives the measured data and the estimated data of storage battery 1, and an estimation model for estimating the degradation state of storage battery 1, via communication I/F 42 of storage battery state estimation device 100a.

Degradation state display 52 is a device that displays the degradation state of storage battery 1 estimated by storage battery state estimation device 100a. Estimation model transmitter 53 is a device that transmits a new estimation model for estimating the degradation state of storage battery 1 to storage battery state estimation device 100a. Measured data and estimated data receiver 54 is a device that receives the data measured and estimated by storage battery state estimation device 100a.

In the degradation state estimation device for storage battery 1 according to Embodiment 1 of the present disclosure, degradation state estimator 321 of storage battery state estimator 30a estimates the capacity retention rate (SOH) of storage battery 1 by using an estimation model trained by machine learning. The estimation model uses the voltage change amount and the electric charge change amount of storage battery 1 as inputs, and outputs the capacity retention rate (SOH) that is the degradation state of storage battery 1.

### [Capacity Retention Rate (SOH) of Storage Battery]

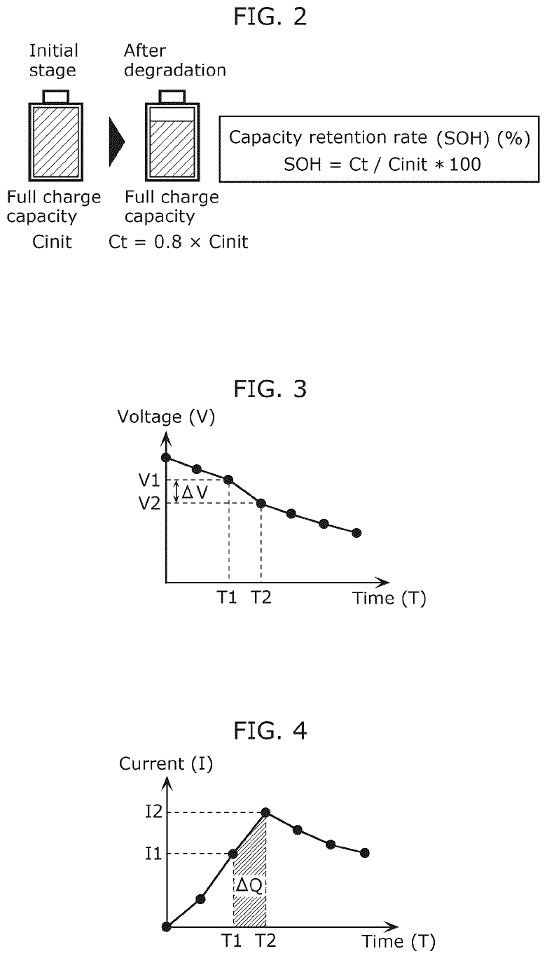

FIG. 2 is a diagram for explaining the capacity retention rate (SOH) of storage battery 1.

When the initial full charge capacity of storage battery 1 is Cinit, storage battery 1 will degrade as storage battery1 continues to be used, and full charge capacity Ct after degradation will be smaller than initial full charge capacity Cinit. FIG. 2 illustrates, as an example, a case in which full charge capacity Ct after degradation has decreased to 80% of initial full charge capacity Cinit. The capacity retention rate (SOH) (%) of storage battery 1 is the ratio of the full charge capacity Ct after degradation to the initial full charge capacity Cinit, and is expressed by following equation 1.

SOH=Ct/Cinit×100 (Equation 1)

In the embodiments of the present disclosure, a degradation estimation device and a degradation estimation method for storage battery 1 that are capable of estimating the degradation state of storage battery 1 even when storage battery 1 is in use and are capable of estimating the capacity retention rate (SOH) of storage battery 1 with higher accuracy.

### [Calculation of Voltage Change Amount and Electric Charge Change Amount of Storage Battery]

A method will be described which calculates the voltage change amount and the electric charge change amount of storage battery 1, which are inputs for calculating the capacity retention rate (SOH) of storage battery 1 by using an estimation model trained by machine learning.

FIG. 3 is a diagram for explaining the voltage measured when storage battery 1 according to Embodiment 1 of the present disclosure is charged and discharged, and the calculation of the voltage change amount. By measuring the voltage of storage battery 1 successively, changes in voltage of storage battery 1 can be assessed. Voltage change amount ΔV can be obtained by obtaining voltage value V1 at time T1 and voltage value V2 at subsequent time T2, and calculating difference V2-V1 between voltage value V1 and voltage value V2. By repeating this operation, a plurality of voltage change amounts can be obtained according to the usage condition of storage battery 1.

FIG. 4 is a diagram for explaining the current measured when storage battery 1 according to Embodiment 1 of the present disclosure is charged and discharged, and the calculation of the electric charge change amount. By measuring the current of storage battery 1 successively, changes in current of storage battery 1 can be assessed. By obtaining current value I1 at time T1 and then current value I2 at time T2, and integrating the current values as illustrated in the shaded area in FIG. 4, the electric charge change amount ΔQ can be obtained. By repeating this operation, a plurality of electric charge change amounts can be obtained according to the usage condition of storage battery 1.

The calculation of voltage change amount ΔV and electric charge change amount ΔQ of storage battery 1 described above is performed by voltage change amount calculator 22 and electric charge change amount calculator 25 of storage battery measurer 20a in the degradation estimation device for storage battery 1 illustrated in FIG. 1. Voltage change amount calculator 22 is an example of a first calculator, and electric charge change amount calculator 25 is an example of a second calculator.

### [Configuration of Storage Battery Degradation State Estimator]

An example will be described which is related to a degradation state estimator for storage battery 1 that calculates the capacity retention rate (SOH) of storage battery 1 by using an estimation model trained by machine learning, that is, related to degradation state estimator 321 of degradation state calculator 32a of storage battery state estimator 30a in the storage battery state estimation device for storage battery 1 illustrated in FIG. 1.

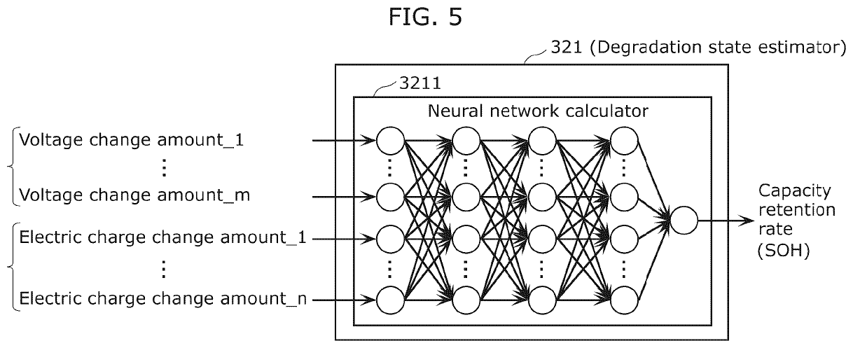

FIG. 5 illustrates a configuration of the degradation state estimator according to Embodiment 1 of the present disclosure. Degradation state estimator 321 calculates the capacity retention rate (SOH) of storage battery 1 by using an estimation model trained by machine learning. The estimation model uses one or more voltage change amounts and one or more electric charge change amounts as inputs, and outputs the capacity retention rate (SOH) of storage battery 1. Degradation state estimator 321 is configured from neural network calculator 3211, and neural network calculator 3211 is configured from a fully connected neural-network (FCN).

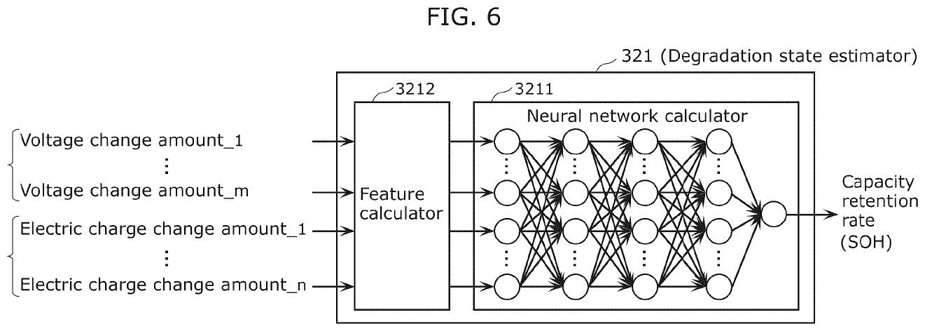

FIG. 6 illustrates another configuration of the degradation state estimator according to Embodiment 1 of the present disclosure. Degradation state estimator 321 in FIG. 5 includes only neural network calculator 3211, in which one or more voltage change amounts and one or more electric charge change amounts are directly input to neural network calculator 3211. Degradation state estimator 321 in FIG. 6 differs from degradation state estimator 321 in FIG. 5 in that feature calculator 3212 is added in the preceding stage of neural network calculator 3211. In other words, in degradation state estimator 321 in FIG. 6, one or more voltage change amounts and one or more electric charge change amounts are input to feature calculator 3212. Feature calculator 3212 calculates new feature values, such as the average values of one or more voltage change amounts and one or more electric charge change amounts, and the difference in change amounts, for example, and the output of feature calculator 3212 is input to neural network calculator 3211. Feature calculator 3212 calculates the optimal features for machine learning, and the capacity retention rate (SOH) of storage battery 1 is estimated by machine learning with the features as input.

In the present embodiment, a case has been described in which the estimation model that uses machine learning of neural network calculator 3211 is FCN. However, the estimation model may be machine learning estimation models other than FCN, such as a recurrent neural network (RNN), a decision tree machine learning estimation model, or a multiple regression analysis machine learning estimation model.

### [Flowchart of Storage Battery Degradation Estimation Method]

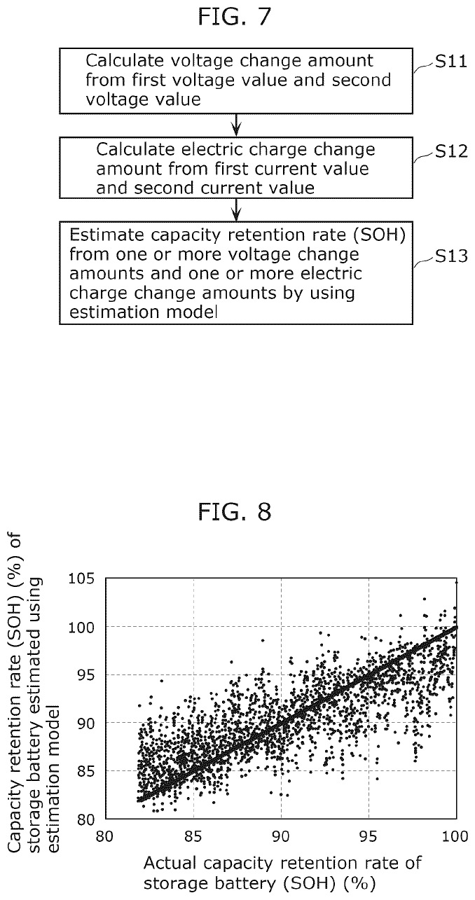

FIG. 7 is a flowchart illustrating a storage battery degradation estimation method according to Embodiment 1 of the present disclosure.

Voltage change amount calculator 22 first calculates the voltage change amount from a first voltage value and a second voltage value measured when storage battery 1 is charged and discharged (S11). Next, electric charge change amount calculator 25 calculates the electric charge change amount from a first current value and a second current value measured when the storage battery is charged and discharged (S12). Finally, degradation state estimator 321 estimates the capacity retention rate (SOH) of storage battery 1 from one or more voltage change amounts and one or more electric charge change amounts by using an estimation model (S13). The second voltage value is the voltage value obtained after the first voltage value. The second voltage value may be the voltage value obtained successively after the first voltage value, or may be the voltage value obtained after a predetermined time interval. The second current value is the current value obtained after the first current value. The second current value may be the current value obtained successively after the first current value, or may be the current value obtained after a predetermined time interval. The first voltage value and the first current value may be obtained at the same time or different times. Similarly, the second voltage value and the second current value may be obtained at the same time or different times.

As described above, in the present embodiment, the input data for estimating the capacity retention rate (SOH) of storage battery 1 is the voltage (voltage change amount) and current (electric charge change amount) measured when storage battery 1 is used, and the measured data of storage battery 1 in the fully charged state is not required. Therefore, it is possible to estimate the degradation state of storage battery 1 even when storage battery 1 is in use. Moreover, the capacity retention rate (SOH) of storage battery 1 is calculated by using an estimation model trained by machine learning. Hence, it is possible to estimate the degradation state of storage battery 1 in various usage conditions by preparing a large amount of learning data and training an estimation model by machine learning. Therefore, it is possible to estimate the degradation state of storage battery 1 with higher accuracy.

### [Estimated Result of Capacity Retention Rate (SOH) of Storage Battery]

By applying Embodiment 1 of the present disclosure, training data for an estimation model that estimates the capacity retention rate (SOH) of storage battery 1 was prepared, and the estimation model was trained. Subsequently, the estimation model trained by machine learning was used to actually estimate the capacity retention rate (SOH) of storage battery 1. The estimated results will be described.

FIG. 8 illustrates the estimated results of degradation of storage battery 1 according to Embodiment 1 of the present disclosure. In FIG. 8, the number of items of training data is approximately 5000, which is a significantly small number compared to the number of items of training data used in developing an estimation model for estimating the degradation state of storage battery 1 installed in an actual product. The results are intended to provide a simple verification of the effectiveness of the present disclosure.

In FIG. 8, the actual capacity retention rate (SOH) of storage battery 1 is represented on the horizontal axis, and the capacity retention rate (SOH) of storage battery 1 estimated by using an estimation model trained by machine learning is represented on the vertical axis. In other words, in FIG. 8, the value on the horizontal axis and the value on the vertical axis plotted at the same position indicate that the estimated result of the capacity retention rate (SOH) of storage battery 1 obtained by using an estimation model trained by machine learning is a correct estimation of the actual capacity retention rate (SOH) of storage battery 1.

As illustrated in FIG. 8, although the number of items of training data is approximately 5000, it is shown that the capacity retention rate (SOH) of storage battery 1 estimated by using the estimation model trained by machine learning could estimate the actual capacity retention rate (SOH) of storage battery 1. However, some of the capacity retention rates (SOH) of storage battery 1 estimated by using the estimation model trained by machine learning included a maximum error of approximately 8% of the actual capacity retention rate (SOH) of storage battery 1. For this, it is possible to reduce errors by optimizing the training method of the estimation model or by increasing the number of items of training data to develop a more accurate estimation model.

The training data is data in which the voltage (the voltage change amount) and current (the electric charge change amount) are input information and the capacity retention rate (SOH) at that time is output information.

[Reception of New Estimation Model for Estimating Degradation State of Storage Battery from Outside and Update]

The storage battery degradation estimation device according to an embodiment is capable of updating the estimation model stored in the storage battery degradation device for storage battery 1 by receiving a new estimation model for estimating the capacity retention rate (SOH) of storage battery 1 from the outside of the storage battery degradation estimation device.

When a new estimation model that is capable of estimating the capacity retention rate (SOH) of storage battery 1 with higher accuracy is developed for the degradation estimation device for storage battery 1 illustrated in FIG. 1, the new estimation model is transmitted from estimation model transmitter 53 to estimation model updater 35 of storage battery state estimator 30a of storage battery state estimation device 100a via communication I/F 51 and communication I/F 42. Estimation model updater 35 is then capable of updating the estimation model stored in estimation model storage 34 with the new estimation model.

As described above, in the present embodiment, even after the degradation estimation device for storage battery 1 is installed in a product, it is possible to perform update to the estimation model that has been trained by adding new training data and is capable of estimating the degradation state of storage battery 1 with higher accuracy. Accordingly, it is possible to estimate the degradation state of storage battery 1 with higher accuracy.

### [Accumulation and Transmission of Measured Data and Estimated Data of Storage Battery to Outside]

The degradation estimation device for storage battery 1 according to Embodiment 1 of the present disclosure is capable of transmitting, to the outside of the degradation estimation device, the measured data of storage battery 1 and the estimated data of the degradation state of storage battery 1.

In the deterioration estimation device for storage battery 1 illustrated in FIG. 1, the measured data of storage battery 1 stored in measured data storage 31 and the estimated data of the deterioration state of storage battery 1 stored in estimated data storage 33 can be transmitted via communication I/F 42 and communication I/F 51 to external measured data and estimated data receiver 54.

As described above, in the present embodiment, it is possible to collect the measured data of storage battery 1 and the estimated data of the degradation state of storage battery 1 even after the degradation estimation device for storage battery 1 is installed in a product. Therefore, it is possible to collect training data in various usage conditions of storage battery 1, and new estimation models with higher accuracy can be trained and updated. Accordingly, it is possible to estimate the degradation state with higher accuracy.

### Embodiment 2

### [Overall Configuration of Storage Battery Degradation Estimation Device]

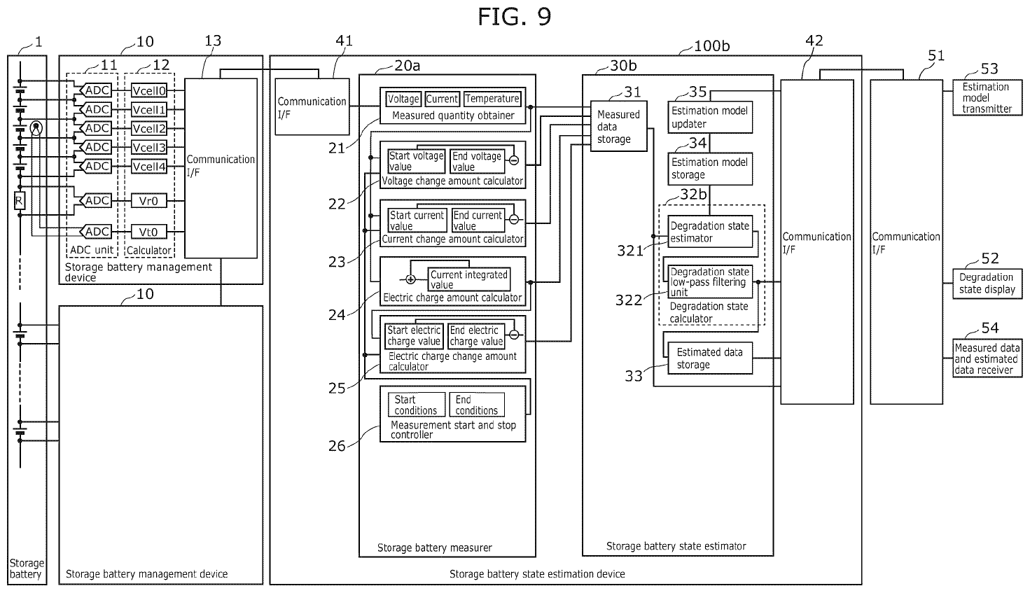

FIG. 9 illustrates an overall configuration of a storage battery degradation estimation device according to Embodiment 2 of the present disclosure. In FIG. 9, the same names, reference numerals, and numbers are given to the structural elements identical to those in FIG. 1 that is the degradation estimation device for storage battery 1 according to Embodiment 1 described above, and a detailed description thereof is omitted.

The degradation estimation device for storage battery 1 according to Embodiment 2 differs from Embodiment 1 in the configuration of storage battery state estimator 30b of storage battery state estimation device 100b in FIG. 9. Specifically, degradation state calculator 32b of storage battery state estimator 30b additionally includes degradation state low-pass filtering unit 322 at the output of degradation state estimator 321. The output of degradation state low-pass filtering unit 322 is connected to degradation state display 52 via communication I/F 42 and communication I/F 51. The output of degradation state low-pass filtering unit 322 is further connected to estimated data storage 33.

### [Configuration of Storage Battery Degradation State Low-Pass Filtering Unit]

Degradation state low-pass filtering unit 322 performs filtering to smooth input data, which is time series data, and output the smoothed data as output data. If n is an integer value, the n-th output data y[n] of degradation state low-pass filtering unit 322 is determined by the previously output (n−1)-th output data y[n−1] and the n-th input data x[n], and is expressed by Equation 2 below.

y[n]=k×x[n]+(1−k)×y[n−1] (Equation 2)

Here, constant k is called time constant, and values such as k=0.1, 0.01, or 0.001 are employed. In other words, n-th output data y[n] of degradation state low-pass filtering unit 322 follows the previously output (n−1)-th output data y[n−1] and is output data in which n-th input data x[n] is also reflected. Degradation state low-pass filtering unit 322 functions as a filtering processor that smoothes the time-series input data and outputs the smoothed input data as output data.

### [Flowchart of Storage Battery Degradation Estimation Method]

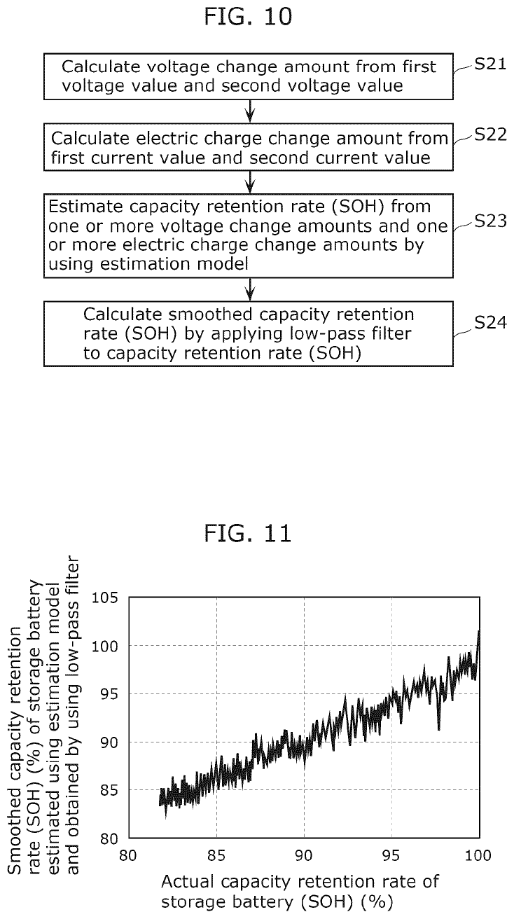

FIG. 10 is a flowchart illustrating a storage battery degradation estimation method according to Embodiment 2 of the present disclosure.

Voltage change amount calculator 22 first calculates the voltage change amount from the first voltage value and the second voltage value measured when storage battery 1 is charged and discharged (S21). Next, electric charge change amount calculator 25 calculates the electric charge change amount from the first current value and the second current value measured when storage battery 1 is charged and discharged (S22). Next, degradation state estimator 321 estimates the capacity retention rate (SOH) of storage battery 1 from one or more voltage change amounts and one or more electric charge change amounts, by using an estimation model (S23). Finally, degradation state low-pass filtering unit 322 calculates the smoothed capacity retention rate (SOH) of storage battery 1 by applying a low-pass filter to the capacity retention rate (SOH) of storage battery 1 calculated in step S23 (S24).

As described above, in the present embodiment, the degradation state of storage battery 1 calculated by using an estimation model is used as input, the degradation state of storage battery 1 is smoothed by using a low-pass filter, and the smoothed degradation state is output. With this, even when the degradation state of storage battery 1 calculated by using the estimation model includes a large error relative to the actual degradation state of storage battery 1 at a given time, the data to be output is smoothed by filtering such that the data follows the previous output data and the smoothed data is output. Therefore, it is possible to estimate the degradation state of storage battery 1 with fewer errors.

### [Estimated Result of Capacity Retention Rate (SOH) of Storage Battery]

FIG. 11 illustrates the estimated results of degradation of a storage battery according to Embodiment 2 of the present disclosure. In FIG. 11, the training data used to train the estimation model and the input data used to estimate the capacity retention rate (SOH) of storage battery 1 are identical to those in Embodiment 1 described above. The differences between the estimated results of degradation of storage battery 1 according to Embodiment 2 illustrated in FIG. 11 and the estimated results of estimation of storage battery 1 according to Embodiment 1 illustrated in FIG. 8 are due to the filtering performed by degradation state low-pass filtering unit 322 in degradation state calculator 32b of storage battery state estimator 30b in Embodiment 2 of the present disclosure illustrated in FIG. 9.

In FIG. 11, the horizontal axis indicates the actual capacity retention rate (SOH) of storage battery 1, and the vertical axis indicates the smoothed capacity retention rate (SOH) of storage battery 1 obtained by applying a low-pass filter to the capacity retention rate (SOH) of storage battery 1 estimated by using an estimation model trained by machine learning. In other words, in FIG. 11, the value on the horizontal axis and the value on the vertical axis plotted at the same position indicate that the capacity retention rate (SOH) of storage battery 1 smoothed by applying a filtering process to the capacity retention rate (SOH) of storage battery 1 by using an estimation model trained by machine learning is a correct estimation of the value of the actual capacity retention rate (SOH) of storage battery 1.

As illustrated in FIG. 11, although the number of items of training data is approximately 5000 which is the same as those in Embodiment 1, it is shown that the capacity retention rate (SOH) of storage battery 1 estimated by using the estimation model trained by machine learning is a correct estimation of the actual capacity retention rate (SOH) of storage battery 1. Furthermore, compared to the estimated results in Embodiment 1 in FIG. 8, the estimated results in Embodiment 2 in FIG. 11 show that the maximum error relative to the actual capacity retention rate (SOH) of storage battery 1 is significantly reduced. In other words, the estimated results in Embodiment 1 in FIG. 8 include a maximum error of approximately 8% with respect to the actual capacity retention rate (SOH) of storage battery 1, while the estimated results in Embodiment 2 in FIG. 11 include a maximum error reduced to approximately 5% or less with respect to the actual capacity retention rate (SOH) of storage battery 1. In Embodiment 2, too, estimations include errors, which can be reduced by optimizing the training method of the estimation model or by further increasing the number of items of training data to develop a more accurate estimation model.

### Embodiment 3

### [Overall Configuration of Storage Battery Degradation Estimation Device]

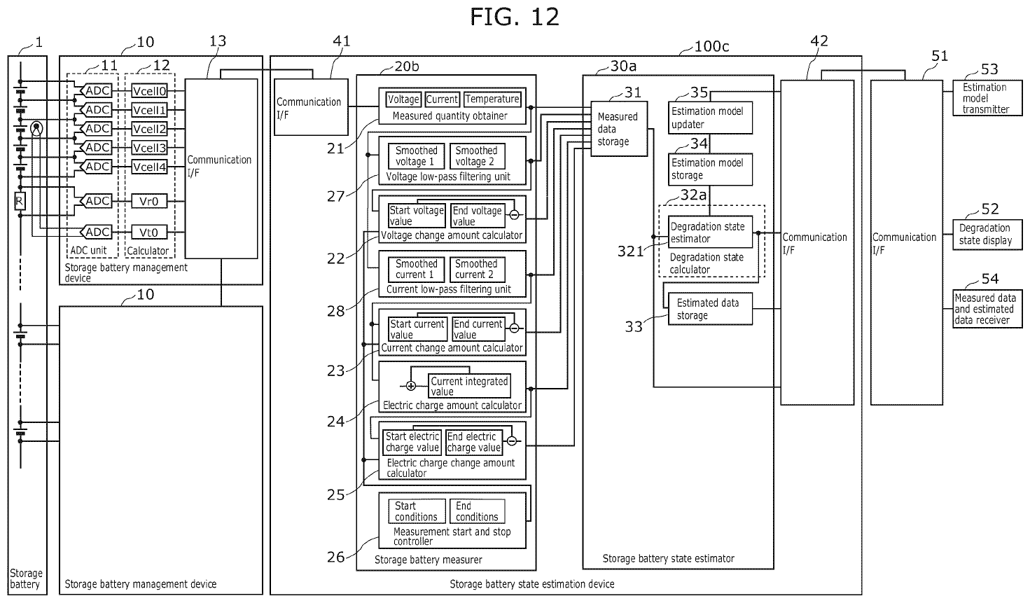

FIG. 12 illustrates an overall configuration of a storage battery degradation estimation device according to Embodiment 3 of the present disclosure. In FIG. 12, the same names, reference numerals, and numbers are given to the structural elements identical to those in FIG. 1 that is the degradation estimation device for storage battery 1 according to Embodiment 1 described above, and a detailed description thereof is omitted.

The degradation estimation device for storage battery 1 according to Embodiment 3 differs from Embodiment 1 in the configuration of storage battery measurer 20b of storage battery state estimation device 100c in FIG. 12. Specifically, the degradation estimation device for storage battery 1 according to Embodiment 3 additionally includes, in storage battery measurer 20b, voltage low-pass filtering unit 27 and current low-pass filtering unit 28. Voltage low-pass filtering unit 27 smoothes the voltage value input from a low-pass filter, and outputs the voltage value as a smoothed voltage value. Current low-pass filtering unit 28 smoothes the current value input from a low-pass filter, and outputs the current value as a smoothed current value. The filtering performed by voltage low-pass filtering unit 27 and current low-pass filtering unit 28 in the present embodiment is the same as the filtering performed by degradation state low-pass filtering unit 322 in Embodiment 2 described above, and its detailed description is omitted.

In the present embodiment, in storage battery measurer 20b, the voltage value obtained by measured quantity obtainer 21 is input to voltage low-pass filtering unit 27, and output as smoothed voltage. The smoothed voltage output from voltage low-pass filtering unit 27 is input to voltage change amount calculator 22, and the amount of change in smoothed voltage (smoothed voltage change amount) is calculated by voltage change amount calculator 22 and stored in measured data storage 31 of storage battery state estimator 30a. Similarly, the current value obtained by measured quantity obtainer 21 is input to current low-pass filtering unit 28 and output as smoothed current. The smoothed current output from current low-pass filtering unit 28 is input to current change amount calculator 23 and electric charge amount calculator 24, and the output of electric charge amount calculator 24 is input to electric charge change amount calculator 25 to calculate the amount of change in smoothed electric charge (smoothed electric charge change amount). The smoothed electric charge change amount calculated by electric charge change amount calculator 25 is stored in measured data storage 31 of storage battery state estimator 30a.

The estimation model for calculating the capacity retention rate (SOH) of storage battery 1 stored in estimation model storage 34 of storage battery state estimator 30a is an estimation model trained by machine learning. The estimation model uses the smoothed voltage value and the smoothed current value as inputs and outputs the capacity retention rate (SOH) of storage battery 1.

The degradation estimation device for storage battery 1 according to Embodiment 3 of the present disclosure: calculates a smoothed voltage value and a smoothed current value which are obtained by respectively smoothing the voltage value and the current value measured from storage battery 1 by using a voltage low-pass filter and a current low-pass filter; calculates the smoothed voltage change amount from the smoothed voltage value and the smoothed electric charge change amount from the smoothed current value; and calculates the capacity retention rate (SOH) of storage battery 1 by using an estimation model trained by machine learning. The estimation model uses the smoothed voltage change amount and the smoothed electric charge change amount as inputs, and outputs the capacity retention rate (SOH) of storage battery 1.

[Voltage Measured from Storage Battery and Smoothed Voltage Smoothed by Using Low-Pass Filter]

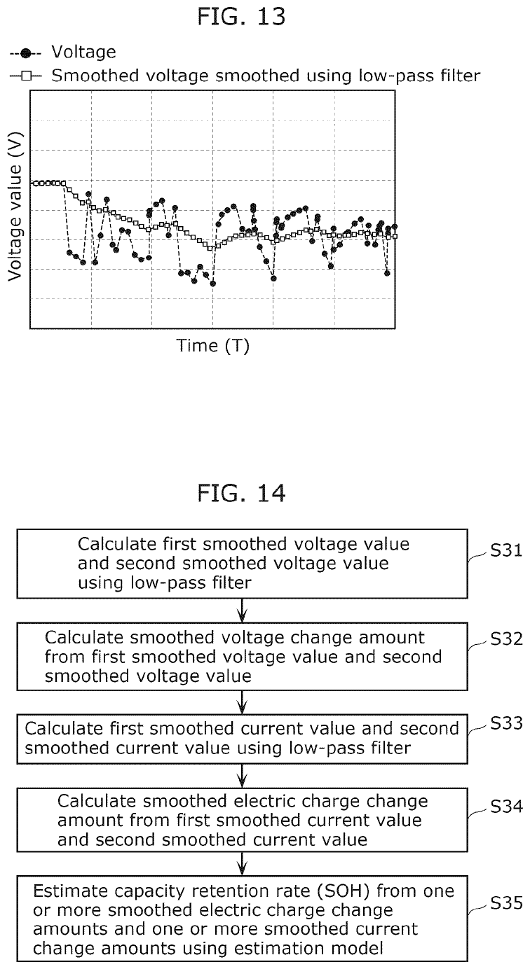

FIG. 13 is a diagram for explaining the voltage measured when a storage battery according to Embodiment 3 of the present disclosure is charged and discharged, and the smoothed voltage smoothed by using a low-pass filter.

In FIG. 13, time is represented on the horizontal axis and voltage value is represented on the vertical axis. FIG. 13 illustrates the voltage measured from storage battery 1 and the smoothed voltage obtained by smoothing the voltage measured from storage battery 1 by using a voltage low-pass filter (voltage low-pass filtering unit 27).

As illustrated in FIG. 13, the voltage measured from storage battery 1 may be affected by sharp changes in charge and discharge current of storage battery 1, measurement noise, and the like, causing discrete voltage changes that are not continuous for each measurement. By using a low-pass filter, the discrete voltage values measured from storage battery 1 are smoothed to follow the previously measured voltage value. Therefore, the voltage change amount input to the estimation model that estimates the degradation state of storage battery 1 is also a smoothed continuous value, making it possible to eliminate the effects of noise and the like from the voltage value of storage battery 1 and the voltage change amount. As a result, it is possible to estimate the degradation state of storage battery 1 with fewer errors. Here, FIG. 13 relates to the voltage measured from storage battery 1 and the smoothed voltage, but the same also applies to the current measured from storage battery 1 and the smoothed current.

### [Flowchart of Storage Battery Degradation Estimation Method]

FIG. 14 is a flowchart of the storage battery degradation estimation method according to Embodiment 3 of the present disclosure.

First, voltage low-pass filtering unit 27 calculates the first smoothed voltage value and the second smoothed voltage value by applying a low-pass filter to the voltage measured when storage battery 1 is charged and discharged (S31). Next, voltage change amount calculator 22 calculates the smoothed voltage change amount from the first smoothed voltage value and the second smoothed voltage value calculated in step S31 (S32). Next, current low-pass filtering unit 28 calculates the first smoothed current value and the second smoothed current value by applying a low-pass filter to the current measured when storage battery 1 is charged and discharged (S33). Next, electric charge change amount calculator 25 calculates the smoothed electric charge change amount from the first smoothed current value and the second smoothed current value calculated in step S33 (S34). Finally, degradation state estimator 321 estimates the capacity retention rate (SOH) of storage battery 1 from one or more smoothed voltage change amounts and one or more smoothed electric charge change amounts by using an estimation model (S35).

As described above, in the present embodiment, the degradation state of storage battery 1 is calculated by using an estimation model trained by machine learning in which the voltage and the current measured when storage battery 1 is charged and discharged are used as inputs, the voltage and the current of storage battery 1 are smoothed by using a low-pass filter to output the smoothed voltage and the smoothed current, the smoothed voltage change amount and the smoothed electric charge change amount obtained from the smoothed voltage and the smoothed current are used as inputs, and the degradation state of storage battery 1 is output. With this, even when the voltage and the current measured from storage battery 1 may be affected by sharp changes in charge and discharge current of storage battery 1, measurement noise, and the like, causing discrete voltage changes and current changes that are not continuous for each measurement, the discrete voltage changes and current changes are smoothed by using a low-pass filter to follow the previously measured voltage and current. Accordingly, the voltage change amount and the electric charge change amount input to the estimation model that estimates the degradation state of storage battery 1 are continuous data. It is possible to eliminate the effects of noise and the like from the voltage change amount and the electric charge change amount that are continuous data. This makes it possible to estimate the degradation state of storage battery 1 with fewer errors.

### Embodiment 4

[Overall Configuration of Storage Battery Degradation Estimation Device]

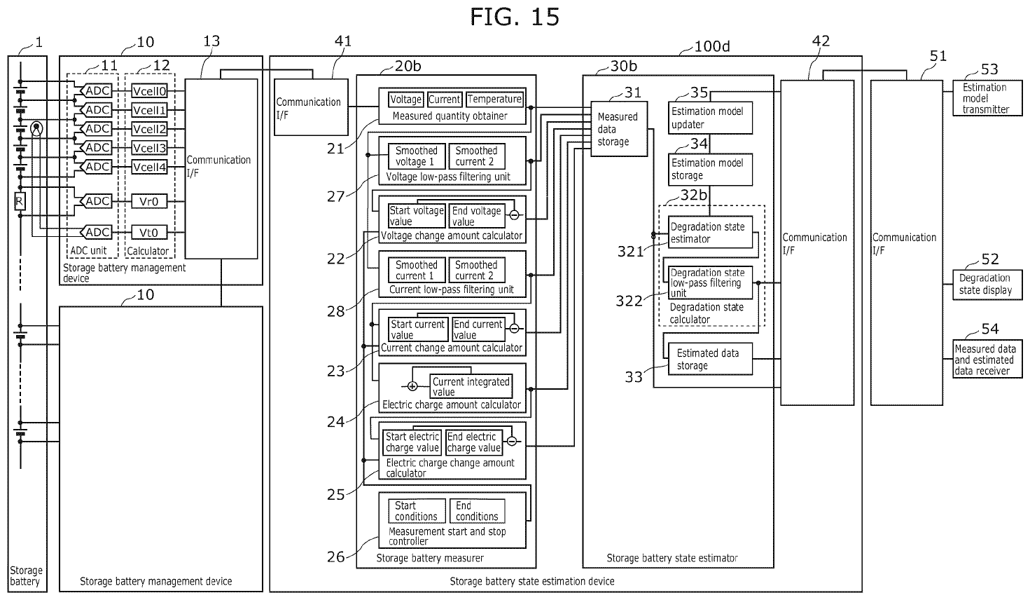

FIG. 15 illustrates an overall configuration of a storage battery degradation estimation device according to Embodiment 4 of the present disclosure. In FIG. 15, the same names, reference numerals, and numbers are given to the structural elements identical to those in any of FIG. 1, FIG. 9, and FIG. 12 which are the degradation estimation devices for storage battery 1 according to Embodiment 1, Embodiment 2, and Embodiment 3 described above, and a detailed description thereof is omitted.

In the degradation estimation device for storage battery 1 according to Embodiment 4, the configuration of storage battery measurer 20b of storage battery state estimation device 100d is identical to Embodiment 3, and the configuration of storage battery state estimator 30b is identical to Embodiment 2. In other words, the degradation estimation device for storage battery 1 according to Embodiment 4 calculates, as described in Embodiment 2 and Embodiment 3, applies a low-pass filter to the voltage and the current measured from storage battery 1 to calculate the smoothed voltage and the smoothed current, calculates the smoothed voltage change amount and the smoothed electric charge change amount from the smoothed voltage and the smoothed current, calculates the capacity retention rate (SOH) of storage battery 1 by using an estimation model trained by machine learning with the smoothed voltage change amount and the smoothed electric charge change amount as inputs and the capacity retention rate (SOH) of storage battery 1 as an output, and further applies a low-pass filter to the capacity retention rate (SOH) of storage battery 1 calculated by using the estimation model to calculate a smoothed capacity retention rate (SOH) of storage battery 1.

### [Flowchart of Storage Battery Degradation Estimation Method]

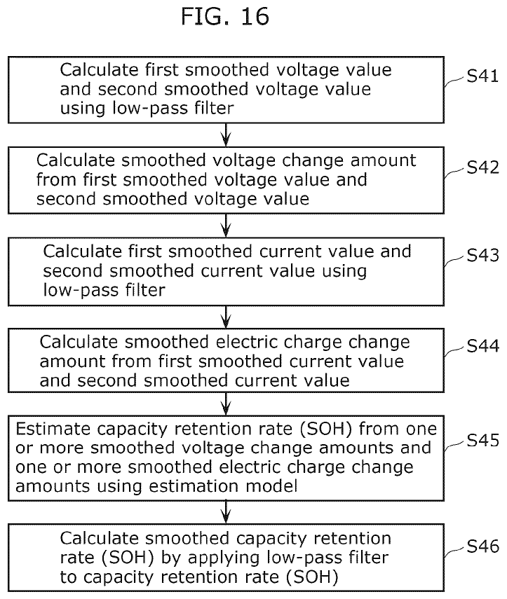

FIG. 16 is a flowchart of a storage battery degradation estimation method according to Embodiment 4 of the present disclosure.

First, voltage low-pass filtering unit 27 calculates a first smoothed voltage value and a second smoothed voltage value by applying a low-pass filter to the voltage measured when storage battery 1 is charged and discharged (S41). Next, voltage change amount calculator 22 calculates the smoothed voltage change amount from the first smoothed voltage value and the second smoothed voltage value calculated in step S41 (S42). Next, current low-pass filtering unit 28 calculates a first smoothed current value and a second smoothed current value by applying a low-pass filter to the current measured when storage battery 1 is charged and discharged (S43). Next, electric charge change amount calculator 25 calculates the smoothed electric charge change amount from the first smoothed current value and the second smoothed current value calculated in step S43 (S44). Next, degradation state estimator 321 estimates the capacity retention rate (SOH) of storage battery 1 from one or more smoothed voltage change amounts and one or more smoothed electric charge change amounts, by using the estimation model (S45). Finally, degradation state low-pass filtering unit 322 calculates the smoothed capacity retention rate (SOH) of storage battery 1 by applying a low-pass filter to the capacity retention rate (SOH) of storage battery 1 calculated in step S45 (S46).

As described above, in the present embodiment, the voltage and the current measured from storage battery 1 are filtered to calculate a smoothed voltage value and a smoothed current value that are smoothed to follow the previously output voltage value and current value. The degradation state of storage battery 1 is estimated by using an estimation model trained by machine learning. The estimation model uses the smoothed voltage change amount and the smoothed electric charge change amount obtained from the smoothed voltage value and the smoothed current value as inputs, and outputs the degradation state of storage battery 1. With this, it is possible to eliminate the effects of noise and the like from the voltage change amount and the electric charge change amount. This makes it possible to estimate the degradation state of storage battery 1 with fewer errors.

Moreover, the degradation state of storage battery 1 calculated by using the estimation model is used as input, filtering is performed to smooth the degradation state of storage battery 1, and the smoothed degradation state is output. Accordingly, even when the degradation state of storage battery 1 calculated by using the estimation model includes a large error relative to the actual degradation state of storage battery 1 at a given time, the data to be output is filtered and smoothed to follow the previously output data, and the smoothed data is output. Therefore, it is possible to estimate the degradation state of storage battery 1 with fewer errors.

### <Conclusion>

As described above, in the storage battery degradation estimation device and method according to the present disclosure, the voltage change amount and the electric charge change amount are respectively calculated from the voltage and the current measured when the storage battery is charged and discharged, and the degradation state of the storage battery is output by using an estimation model trained by machine learning. The estimation model uses the voltage change amount and the electric charge change amount as inputs, and outputs the degradation state of the storage battery. Accordingly, even when the storage battery is in use, the degradation state can be estimated with higher accuracy.

Furthermore, the degradation state of the storage battery calculated by the estimation model is filtered so that the smoothed degradation state of the storage battery is output. This makes it possible to estimate the degradation state of the storage battery with fewer errors. Furthermore, the voltage and the current measured from the storage battery are filtered to calculate a smoothed voltage value and a smoothed current value, and the smoothed voltage change amount and the smoothed electric charge change amount are calculated from the smoothed voltage value and the smoothed current value, so that the degradation state of the storage battery is estimated. With this, it is possible to eliminate the effects of noise and the like from the voltage and the electric charge measured from the storage battery. This makes it possible to estimate the degradation state of the storage battery with fewer errors.

Furthermore, the estimation model for estimating the degradation state of the storage battery stored in the storage battery degradation estimation device can be updated to a new estimation model. This allows an update to an estimation model that is capable of estimating the degradation state of the storage battery with higher accuracy even after the storage battery degradation estimation device is installed in the product. As a result, it is possible to estimate the degradation state of storage battery with higher accuracy.

Furthermore, a plurality of items of measured data and a plurality of items of estimated data respectively measured and estimated by the storage battery deterioration estimation device can be transmitted to the outside of the storage battery degradation estimation device. This makes it possible to collect measured data of the storage battery when the storage battery is used and the estimated data of the degradation state of the storage battery, even after the storage battery degradation estimation device is installed in a product. This makes it possible to train and update a new estimation model with higher accuracy that uses training data that includes various usage conditions of the storage battery. Therefore, it is possible to estimate the degradation state of the storage battery with higher accuracy.

The embodiments according to the present disclosure have been described above. The storage battery degradation estimation device and the storage battery degradation estimation method according to the present disclosure are not limited to the examples described above, and are also applicable to the forms obtained by various modifications to the embodiments that can be conceived by a person of skill in the art as well as forms realized by arbitrarily combining structural elements in the embodiments which are within the scope of the essence of the present disclosure.

For example, the specific configuration of the storage battery state estimation device in the storage battery degradation estimation device according to the embodiments of the present disclosure is not limited to the configuration described in the embodiments of the present disclosure. In order that the storage battery measurer of the storage battery state estimation device calculates the voltage change amount, the electric charge change amount of the storage battery or the smoothed voltage change amount and the smoothed electric charge change amount of the storage battery, in the present embodiment, a configuration has been described which includes the measured quantity obtainer, the voltage change amount calculator, the current change amount calculator, the electric charge amount calculator, the electric charge change amount calculator, the measurement start and stop controller, the voltage low-pass filtering unit, and the current low-pass filtering unit. However, the present disclosure is not limited to such an example. Other configurations may be used as long as the voltage change amount and the electric charge change amount of the storage battery or the smoothed voltage change amount and the smoothed electric charge change amount of the storage battery can be calculated.

Although the calculation formulas for filtering and smoothing the voltage and the current of the storage battery and the degradation state of the storage battery have been described in the present embodiment, the present disclosure is not limited to such an example. Another calculation formula that enables smoothing may be employed.

Moreover, an estimation model that uses the fully connected neural network has been described in the present embodiment as an estimation model trained by machine learning, but the present disclosure is not limited to such an example. For example, an estimation model capable of estimating the degradation state of a storage battery, such as a recurrent neural network, a decision tree machine learning estimation model, or a multiple regression analysis machine learning estimation model, may be employed.

In the embodiments described above, each structural element may be configured in the form of a dedicated hardware product or realized by executing a software program suitable for each structural element. Each of the structural elements may be realized by means of a program executing unit, such as a central processing unit (CPU) and a processor, reading and executing the software program recorded on a recording medium such as a hard disk or a semiconductor memory.

The order in which the steps in the flowcharts are executed has been specified to provide a specific illustration of the present disclosure. The steps may be executed in any other order. In addition, some of the steps may be executed at the same time as (in parallel with) another step, or do not have to be executed.

Moreover, the separation of the function blocks in the block diagrams is merely an example, and plural function blocks may be implemented as a single function block, a single function block may be separated into plural function blocks, or part of functions of a function block may be transferred to another function block. Moreover, the functions of function blocks having similar functions may be processed, in parallel or in a time-division manner, by a single hardware or software.

Each structural element described in the above embodiments may be implemented as a software, or as a large scale integration (LSI) which is an integrated circuit (IC). They may be individually configured as single chips or may be configured so that part or all are included in a single chip. The name used here is LSI, but it may also be called IC, VLSI, ULSI, or system LSI depending on the degree of integration. The method of circuit integration is not limited to LSIs, and implementation through a dedicated circuit or a general-purpose processor is also possible.

Moreover, an aspect of the present disclosure may be a computer program causing a computer to execute the characteristic steps included in the storage battery degradation estimation method illustrated in any of FIG. 7, FIG. 10, FIG. 14, and FIG. 16.

Moreover, for example, the program may be a program to be executed by a computer. Moreover, an aspect of the present disclosure may also be a non-transitory computer-readable recording medium on which this sort of computer program is recorded. For example, such a program may be recorded on a recording medium for distribution. For example, the distributed program is installed in a device that includes another processor, and the program is executed by the processor, so that the device is capable of performing various processes.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The storage battery degradation estimation device and the storage battery degradation estimation method according to the present disclosure are capable of estimating the degradation state of a storage battery even when the storage battery is in use, and are capable of estimating the degradation state with higher accuracy. Accordingly, the storage battery degradation estimation device and the storage battery degradation estimation method according to the present disclosure are useful to devices that (i) operate continuously for long hours and long periods with storage batteries as their power source, and (ii) would significantly affect business execution or system operation when the devices were to run out of power or have malfunction. Examples of such devices include electric bicycles, electric motorcycles, electric automobiles, electric airplanes, electric ships, electric agricultural machines, drones, automatic transporters, industrial robots, and energy storage systems.

1. A storage battery degradation estimation device that estimates a degradation state of a storage battery from a measurement result of the storage battery, the storage battery degradation estimation device comprising:
a first calculator that calculates a voltage change amount that is an amount of change in a voltage of the storage battery obtained from a first voltage value and a second voltage value that are measured when the storage battery is charged and discharged, the second voltage value being measured after the first voltage value;
a second calculator that calculates an electric charge change amount that is an amount of change in an electric charge of the storage battery obtained from a first current value and a second current value that are measured when the storage battery is charged and discharged, the second current value being measured after the first current value;
a measured data storage that stores a plurality of items of measured data that include the voltage change amount and the electric charge change amount;
an estimation model storage that stores an estimation model trained by machine learning, the estimation model using one or more voltage change amounts and one or more electric charge change amounts as inputs and outputting the degradation state of the storage battery, the one or more voltage change amounts each being the voltage change amount, the one or more electric charge change amounts each being the electric charge change amount; and
an estimator that estimates the degradation state of the storage battery by using the estimation model stored in the estimation model storage, the estimator using, as inputs, the one or more voltage change amounts and the one or more electric charge change amounts stored in the measured data storage.

2. The storage battery degradation estimation device according to claim 1, further comprising:
a low-pass filtering unit that uses, as an input, the degradation state of the storage battery output from the estimator, smoothes the degradation state of the storage battery by using a low-pass filter to obtain a smoothed degradation state of the storage battery, and outputs the smoothed degradation state.

3. A storage battery degradation estimation device that estimates a degradation state of a storage battery from a measurement result of the storage battery, the storage battery degradation estimation device comprising:
a first low-pass filtering unit that uses, as an input, a voltage measured when the storage battery is charged and discharged, smoothes the voltage by using a low-pass filter to obtain a smoothed voltage, and outputs the smoothed voltage;
a first calculator that calculates a smoothed voltage change amount that is an amount of change in the smoothed voltage of the storage battery obtained from a first smoothed voltage value and a second smoothed voltage value that are output from the first low-pass filtering unit, the second smoothed voltage value being output after the first smoothed voltage value;
a second low-pass filtering unit that uses, as an input, a current measured when the storage battery is charged and discharged, smoothes the current by using a low-pass filter to obtain a smoothed current, and outputs the smoothed current;
a second calculator that calculates a smoothed electric charge change amount that is an amount of change in a smoothed electric charge of the storage battery obtained from a first smoothed current value and a second smoothed current value that are output from the second low-pass filtering unit, the second smoothed current value being output after the first smoothed current value;
a measured data storage that stores a plurality of items of measured data that include the smoothed voltage change amount and the smoothed electric charge change amount;
an estimation model storage that stores an estimation model trained by machine learning, the estimation model using one or more smoothed voltage change amounts and one or more smoothed electric charge change amounts as inputs and outputting the degradation state of the storage battery, the one or more smoothed voltage change amounts each being the smoothed voltage change amount, the one or more electric charge change amounts each being the smoothed electric charge change amount; and
an estimator that estimates the degradation state of the storage battery by using the estimation model stored in the estimation model storage, the estimator using, as inputs, the one or more smoothed voltage change amounts and the one or more smoothed electric charge change amounts stored in the measured data storage.

4. The storage battery degradation estimation device according to claim 3, further comprising:
a third low-pass filtering unit that uses, as an input, the degradation state of the storage battery output from the estimator, smoothes the degradation state of the storage battery by using a low-pass filter to obtain a smoothed degradation state of the storage battery, and outputs the smoothed degradation state.

5. The storage battery degradation estimation device according to claim 1,
wherein the degradation state of the storage battery is a capacity retention rate of the storage battery.

6. The storage battery degradation estimation device according to claim 1,
wherein the degradation state of the storage battery is a full charge capacity value of the storage battery.

7. The storage battery degradation estimation device according to claim 1, further comprising:
a reception communicator that receives a new estimation model from outside of the storage battery degradation estimation device; and
an updater that updates the estimation model stored in the estimation model storage to the new estimation model received by the reception communicator.

8. The storage battery degradation estimation device according to claim 1, further comprising:
an estimated data storage that stores the degradation state of the storage battery estimated by the estimator; and
a transmission communicator that transmits the plurality of items of measured data stored in the measured data storage and the degradation state of the storage battery stored in the estimated data storage to outside of the storage battery degradation estimation device.

9. A storage battery degradation estimation method for estimating a degradation state of a storage battery from a measurement result of the storage battery, the storage battery degradation estimation method comprising:
calculating a voltage change amount that is an amount of change in a voltage of the storage battery obtained from a first voltage value and a second voltage value that are measured when the storage battery is charged and discharged, the second voltage value being measured after the first voltage value;
calculating an electric charge change amount that is an amount of change in an electric charge of the storage battery obtained from a first current value and a second current value that are measured when the storage battery is charged and discharged, the second current value being measured after the first current value; and
estimating the degradation state of the storage battery by using an estimation model trained by machine learning, the estimating using one or more voltage change amounts and one or more electric charge change amounts as inputs, the estimation model using the one or more voltage change amounts and the one or more electric charge change amounts as inputs and outputting the degradation state of the storage battery, the one or more voltage change amounts each being the voltage change amount, the one or more electric charge change amounts each being the electric charge change amount.

10. The storage battery degradation estimation method according to claim 9, further comprising:
using the degradation state of the storage battery as an input, and smoothing the degradation state of the storage battery by using a low-pass filter to calculate a smoothed degradation state of the storage battery.

11. A storage battery degradation estimation method for estimating a degradation state of a storage battery from a measurement result of the storage battery, the storage battery degradation estimation method comprising:
using, as an input, a voltage measured when the storage battery is charged and discharged, and smoothing the voltage by using a low-pass filter to calculate a first smoothed voltage value and a second smoothed voltage value, the second smoothed current value being obtained after the first smoothed voltage value;
calculating a smoothed voltage change amount that is an amount of change in a smoothed voltage of the storage battery obtained from the first smoothed voltage value and the second smoothed voltage value;
using a current measured when the storage battery is charged and discharged, and smoothing the current by using a low-pass filter to calculate a first smoothed current value and a second smoothed current value, the second smoothed current value being obtained after the first smoothed current value;
calculating a smoothed electric charge change amount that is an amount of change in a smoothed electric charge of the storage battery obtained from the first smoothed current value and the second smoothed current value; and
estimating the degradation state of the storage battery by using an estimation model trained by machine learning, the estimating using one or more smoothed voltage change amounts and one or more smoothed electric charge change amounts as inputs, the estimation model using the one or more smoothed voltage change amounts and the one or more smoothed electric charge change amounts as inputs and outputting the degradation state of the storage battery, the one or more smoothed voltage change amounts each being the smoothed voltage change amount, the one or more smoothed electric charge change amounts each being the smoothed electric charge change amount.

12. The storage battery degradation estimation method according to claim 11, further comprising:
using the degradation state of the storage battery as an input, and smoothing the degradation state of the storage battery by using a low-pass filter to calculate a smoothed degradation state of the storage battery.

13. The storage battery degradation estimation method according to claim 9,
wherein the degradation state of the storage battery is a capacity retention rate of the storage battery.

14. The storage battery degradation estimation method according to claim 9,
wherein the degradation state of the storage battery is a full charge capacity value of the storage battery.
